(19) United States
(12) Patent Application Publication
(10) Pub. No.: US 2023/0157043 A1
(43) Pub. Date: May 18, 2023

(54) DISPLAY PANEL AND MANUFACTURING METHOD OF DISPLAY PANEL

(71) Applicant: Shenzhen China Star Optoelectronics Semiconductor Display Technology Co., Ltd., Shenzhen, Guangdong (CN)

(72) Inventor: Yongwei WU, Shenzhen, Guangdong (CN)

(73) Assignee: Shenzhen China Star Optoelectronics Semiconductor Display Technology Co., Ltd., Shenzhen, Guangdong (CN)

(21) Appl. No.: 16/964,222

(22) PCT Filed: Jun. 5, 2020
(86) PCT No.: PCT/CN2020/094733

§ 371 Date: Jul. 23, 2020

(30) Foreign Application Priority Data
May 18, 2020 (CN) 202010420237.0

(51) Int. Cl. H10K 50/115; H10K 50/13; H10K 71/00

(52) U.S. Cl. CPC H10K 50/115; H10K 50/13; H10K 71/00

(57) ABSTRACT

A display panel and a manufacturing method of the display panel are provided. The display panel includes: a first electrode, a second electrode disposed opposite to the first electrode, at least two light-emitting units and at least one charge generation layer disposed between the first electrode and the second electrode, wherein at least one of the light-emitting units is doped with quantum dot light-emitting material, and light emitted by each of the light-emitting units are blended to form white light.

### FIELD OF INVENTION

The invention relates to the field of display technology, in particular to a display panel and a manufacturing method of the display panel.

### BACKGROUND OF INVENTION

The technology of organic light-emitting diode (OLEDs) self-luminosity has gradually become a next-generation mainstream display solution. Based on OLED technology, a screen can be made ultra-thin, bendable, and foldable, which bestows upon the end-product display device great innovative potential and aesthetic value.

The current OLED manufacturing process is based on evaporation technology. In terms of small and medium-size OLEDs, large-scale evaporation equipment and fine metal masks (FMMs) are used to obtain uniformly-arranged R, G, and B pixel-level light-emitting areas on a substrate. However, when the size of the substrate increases past a certain extent, there will be a certain deviation in deposition positions of the organic material. Thus, the evaporation method based on fine metal masks is no longer applicable. Current large-size OLED screens adopt white organic light-emitting diode (WOLED) technology. That is, organic materials of different luminous colors are evaporated onto an entire surface to obtain a uniform white light emission across the entire surface, and a color filter is then used to realize color emission. Current mainstream devices adopt a blue light-emitting layer (B) and a yellow light-emitting layer (Y) to form a stacked structure for emitting white light in a blended manner, which is simple and easy to implement. Under the premise that the evaporation production process is retained, large-scale OLED manufacturing remains possible. However, the color gamut and color purity of such OLEDs are relatively poor. In addition, current commercial blue OLED materials are mostly fluorescent light (theoretical external quantum efficiency is less than 5%), and their luminous efficiency and service life are not satisfactory.

### TECHNICAL PROBLEM

The current display panel has technical problems of relatively poor color gamut and color purity and insufficient luminous efficiency and service life.

### SUMMARY OF INVENTION

Embodiments of the present invention provide a display panel and a manufacturing method thereof, which are used to solve the technical problems that the current display panel has relatively poor color gamut and color purity, insufficient luminous efficiency, and service life.

To solve the above problem, in a first aspect, the present invention provides a display panel, including: a first electrode; a second electrode disposed opposite to the first electrode; at least two light-emitting units and at least one charge generation layer disposed between the first electrode and the second electrode; wherein the at least one charge generation layer is disposed between adjacent light-emitting units, at least one of the light-emitting units is doped with quantum dot light-emitting material, and light emitted by each of the light-emitting units is blended to form white light.

In some embodiments of the present invention, the quantum dot light-emitting material includes a blue quantum dot light-emitting material, and at least one of the light-emitting units includes a blue quantum dot light-emitting layer.

In some embodiments of the present invention, when a number of the light-emitting units doped with the quantum dot light-emitting material is two, they are defined as a first light-emitting unit and a second light-emitting unit, and the first light-emitting unit is disposed opposite to the second light-emitting unit.

In some embodiments of the present invention, further including a third light-emitting unit disposed between the first light-emitting unit and the second light-emitting unit, wherein the third light-emitting unit includes a yellow organic light-emitting layer or an organic light-emitting layer formed by stacking a yellow organic light-emitting layer and a red organic light-emitting layer.

In some embodiments of the present invention, the at least one charge generation layer includes a first charge generation layer and a second charge generation layer, the first charge generation layer is disposed between the first light-emitting unit and the third light-emitting unit, and the second charge generation layer is disposed between the third light-emitting unit and the second light-emitting unit.

In some embodiments of the present invention, light-emitting material of the first light-emitting unit is the same as light-emitting material of the second light-emitting unit.

In some embodiments of the present invention, the quantum dot light-emitting material includes cadmium-based quantum dots including at least one of cadmium sulfide, cadmium telluride, or cadmium selenide.

In some embodiments of the present invention, the quantum dot light-emitting material includes at least one of silicon, germanium, zinc selenide, lead sulfide, lead selenide, indium phosphide, or indium arsenide.

In some embodiments of the present invention, further including a hole transport layer, an electron transport layer, and an electron injection layer.

In a second aspect, the present invention provides a method of manufacturing a display panel. The manufacturing method is used to manufacture any of the display panels in the first aspect, and includes following steps: providing a first electrode, and forming at least two light-emitting units and at least one charge generation layer on the first electrode;

and forming a second electrode on the light-emitting unit or the charge generation layer; wherein at least one of the light-emitting units is doped with quantum dot light-emitting material.

In some embodiments of the present invention, forming the light-emitting unit doped with the quantum dot light-emitting material adopts a wet process, including spray coating, silk rod coating, or roll-to-roll coating.

In some embodiments of the present invention, the quantum dot light-emitting material includes a blue quantum dot light-emitting material, and at least one of the light-emitting units includes a blue quantum dot light-emitting layer.

In some embodiments of the present invention, when a number of the light-emitting units doped with the quantum dot light-emitting material is two, forming a first light-emitting unit and a second light-emitting unit, respectively, and the first light-emitting unit is disposed opposite to the second light-emitting unit.

In some embodiments of the present invention, further including forming a third light-emitting unit, wherein the third light-emitting unit is formed between the first light-emitting unit and the second light-emitting unit. The third light-emitting unit includes a yellow organic light-emitting layer or an organic light-emitting layer formed by stacking a yellow organic light-emitting layer and a red organic light-emitting layer.

In some embodiments of the present invention, the at least one charge generation layer includes a first charge generation layer and a second charge generation layer, wherein the first charge generation layer is formed between the first light-emitting unit and the third light-emitting unit, and the second charge generation layer is formed between the third light-emitting unit and the second light-emitting unit.

In some embodiments of the present invention, the light-emitting material forming the first light-emitting unit and the light-emitting material forming the second light-emitting unit are the same.

In some embodiments of the present invention, the quantum dot light-emitting material includes cadmium-based quantum dots, including at least one of cadmium sulfide, cadmium telluride, or cadmium selenide.

In some embodiments of the present invention, forming the quantum dot light-emitting material adopts at least one of silicon, germanium, zinc selenide, lead sulfide, lead selenide, indium phosphide, or indium arsenide.

In some embodiments of the present invention, further including forming a hole transport layer, an electron transport layer, and an electron injection layer, the hole transport layer is formed on one surface of the first electrode, the electron injection layer is formed on one surface of the second electrode, and the electron injection layer is formed on one surface of the electron injection layer.

### BENEFICIAL EFFECT

Unlike current display panels, in the display panel of the present invention, at least one organic light-emitting layer is replaced with a light-emitting unit doped with quantum dot light-emitting material. Since the quantum dot light-emitting material has properties of narrow emission spectrum and high stability, the display panel optimizes luminous efficiency and stability of the at least one light-emitting unit while maintaining high screen brightness. Furthermore, the color gamut, color purity, and service life of the display panel are improved.

### DESCRIPTION OF DRAWINGS

In order to more clearly explain the technical solutions in the embodiments of the present invention, the drawings required in the description of the embodiments will be briefly introduced below. Obviously, the drawings in the description are only some embodiments of the present invention. For those skilled in the art, without doing any creative labor, other drawings can be obtained based on these drawings.

FIG. 1 is a schematic structural diagram of a display panel in an embodiment of the invention.

FIG. 2 is a schematic structural diagram of a display panel in an embodiment of the invention.

FIG. 3 is a flowchart of a method of manufacturing a display panel according to an embodiment of the invention.

### DETAILED DESCRIPTION OF PREFERRED EMBODIMENTS

The technical solutions in the embodiments of the present invention will be described clearly and completely reference with the drawings in the embodiments of the present invention. Obviously, the embodiments are only a part of the embodiments of the present invention, but not all the embodiments. Based on the embodiments of the present invention, all other embodiments obtained by those skilled in the art without creative work fall within the protection scope of the present invention.

In the description of this application, it should be understood that the orientations or positional relationships indicated by the terms “center”, “longitudinal”, “transverse”, “length”, “width”, “thickness”, “above”, “below”, “front”, “back”, “left”, “right”, “vertical”, “horizontal”, “top”, “bottom”, “inner”, “outer”, “clockwise”, “counterclockwise” etc., are based on those shown in the drawings. It is only for the convenience of describing the present application and simplifying the description, rather than indicating or implying that the device or element referred to must have a specific orientation, be constructed and operate in a specific orientation, and therefore cannot be construed as a limitation of the present application. In addition, the terms “first” and “second” are used for descriptive purposes only, and cannot be understood as indicating or implying relative importance or implicitly indicating the number of technical features indicated. Thus, the features defined as “first” and “second ” may explicitly or implicitly include one or more of the features. In the description of this application, the meaning of “plurality” is two or more, unless otherwise specifically limited.

The current display panel, upon attachment of a privacy-protection film, has the following technical problems: light transmittance of the display screen decreases which negatively affects display effect and user experience, an increase in overall thickness of a mobile phone, an increase in fragility, and an increase in costs.

Based on these reasons, embodiments of the present invention provide a display panel and a method of manufacturing the display panel, which will be described in detail below.

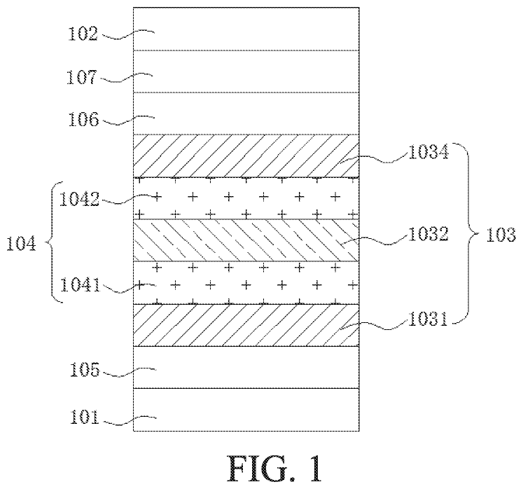

First, the present invention provides a display panel shown in FIG. 1. FIG. 1 is a schematic structural diagram of a display panel according to an embodiment of the present invention. The display panel includes: a first electrode 101; a second electrode 102 disposed opposite to the first electrode 101; at least two light-emitting units 103 and at least one charge generation layer 104 disposed between the first electrode 101 and the second electrode 102; wherein the at least one charge generation layer 104 is disposed between adjacent light-emitting units 103, at least one of the light-emitting units 103 is doped with quantum dot light-emitting material, and light emitted by each of the light-emitting units 103 is blended to form white light.

Unlike current display panels, in the display panel of the present invention, at least one organic light-emitting layer is replaced with a light-emitting unit 103 doped with a quantum dot light-emitting material. Since the quantum dot light-emitting material has a narrow emission spectrum and high stability, the display panel optimizes luminous efficiency and stability of the at least one light-emitting unit 103 while maintaining high screen brightness. Furthermore, the color gamut, color purity, and service life of the display panel are improved.

In an embodiment of the present invention based on the above embodiment, the quantum dot light-emitting material includes a blue quantum dot light-emitting material. At least one of the light-emitting units 103 includes a blue quantum dot light-emitting layer 1031, and one of the light-emitting units 103 is a yellow organic light-emitting layer 1032. The blue quantum dot light-emitting layer 1031 emits a part of blue light to excite yellow fluorescent or phosphorescent conversion material in the yellow organic light-emitting layer 1032. The yellow organic light-emitting layer 1032 emits yellow light, and the yellow light and another part of blue light are blended to form white light.

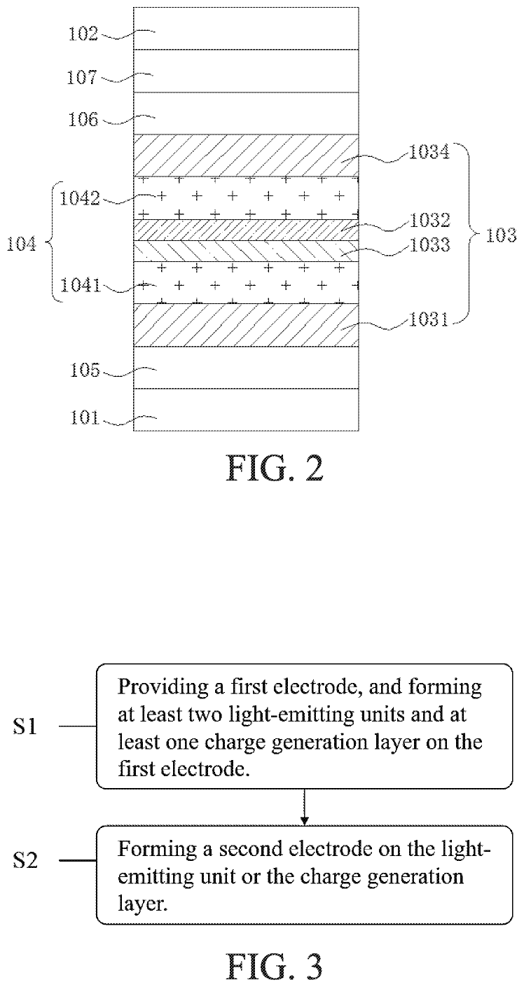

Another embodiment of the present invention as shown in FIG. 2. FIG. 2 is a schematic structural diagram of a display panel in an embodiment of the present invention. When a number of the light-emitting units 103 doped with the quantum dot light-emitting material is two, they are defined as a first light-emitting unit 1031 and a second light-emitting unit 1034, and the first light-emitting unit 1031 is disposed opposite to the second light-emitting unit 1034, wherein at least one of the light-emitting units 103 is a blue quantum dot light-emitting layer.

In an embodiment of the present invention, the display panel further includes a third light-emitting unit disposed between the first light-emitting unit 1031 and the second light-emitting unit 1034. The third light-emitting unit includes a yellow organic light-emitting layer 1032 or an organic light-emitting layer formed by stacking a yellow organic light-emitting layer 1032 and a red organic light-emitting layer 1033.

When the third light-emitting unit only includes the yellow organic light-emitting layer 1032, i.e. when the display panel includes three of the light-emitting units 103, the first light-emitting unit 1031 and the second light-emitting unit 1034 are doped with the quantum dot light-emitting material. The third light-emitting unit is disposed between the first light-emitting unit 1031 and the second light-emitting unit 1034. The first light-emitting unit 1031 and the second light-emitting unit 1034 emit blue light, and the third light-emitting unit emits yellow light, which is blended to form white light.

In the case that the third light-emitting unit includes the yellow organic light-emitting layer 1032 and a red organic light-emitting layer 1033, since the white light formed in the above embodiment lacks a red-light component, the white light obtained has a high color temperature, a low color rendering index, and poor thermal characteristics. In this embodiment, the red organic light-emitting layer 1033 is added, and red fluorescent or phosphorescent conversion materials are excited by a part of blue light, and the red light is blended with the yellow light and another part of blue light to form white light emission.

Based on the above embodiment, the at least one charge generation layer 104 includes a first charge generation layer 1041 and a second charge generation layer 1042, the first charge generation layer 1041 is disposed between the first light-emitting unit 1031 and the third light-emitting unit, and the second charge generation layer 1042 is disposed between the third light-emitting unit and the second light-emitting unit 1034.

The light-emitting material of the first light-emitting unit 1031 is the same as that of the second light-emitting unit 1034. Since energy levels of the two light-emitting units match, less blue light impurities are generated, which can improve display brightness and light-emitting efficiency of the display panel.

In some embodiments, the quantum dot light-emitting material includes cadmium-based quantum dots, including at least one of cadmium sulfide, cadmium telluride, or cadmium selenide. The above materials have advantages of low manufacturing cost, high production yield, and high luminous efficiency. In other embodiments, the quantum dot light-emitting material includes at least one of silicon, germanium, zinc selenide, lead sulfide, lead selenide, indium phosphide, indium arsenide, or perovskite.

Based on the above embodiments, the display panel further includes a hole transport layer 105, an electron transport layer 106, and an electron injection layer 107. Preferably, the first electrode 101 is an anode, and the second electrode 102 is a cathode. The hole transport layer 105 is disposed close to a side of the first electrode 101, the electron injection layer 107 is disposed close to a side of the second electrode 102, and the electron transport layer 106 is disposed between the electron injection layer 107 and the light-emitting unit 103.

Preferably, the red organic light-emitting layer 1033 is close to a side of the first electrode 101, and the yellow organic light-emitting layer 1032 is close to a side of the second electrode 102.

In order to better manufacture the display panel in the embodiment of the present invention, on the basis of the display panel, an embodiment of the present invention also provides a method of manufacturing a display panel, which is used to manufacture the display panel as described in the above embodiment.

As shown in FIG. 3, which is a flowchart of a method for manufacturing a display panel according to an embodiment of the present invention. The manufacturing method includes: S1, providing a first electrode 101, and forming at least two light-emitting units 103 and at least one charge generation layer 104 on the first electrode 101; and S2, forming a second electrode 102 on the light-emitting unit 103 or the charge generation layer 104; wherein at least one of the light-emitting units 103 is doped with quantum dot light-emitting material, and wherein forming the light-emitting unit doped with the quantum dot light-emitting material adopts a wet process, including spray coating, silk rod coating, or roll-to-roll coating.

In the above embodiments, each embodiment has its own emphasis. For a part that is not described in an embodiment, please refer to a detailed description in other embodiments, which will not be repeated here. In a specific implementation, the above units or structures can be implemented as independent entities, or they can be combined in any combination and implemented as the same entity or several entities. For the specific implementation of the units or structures, please refer to foregoing method embodiments, and details are not described herein. Regarding the specific implementation for the above operations, please refer to previous embodiments, and will not be repeated here.

The embodiments of the present invention have been described in detail above, and specific examples are used to explain the principles and implementations of the present invention. The descriptions of the embodiments are only used to help understand the method of the present invention and its core ideas. In addition, the specific implementation and application scope can be modified by those skilled in the art based on the idea of the present invention. As described above, the content of this specification should not be construed as limiting the present invention.

What is claimed is:

1. A display panel, comprising:
a first electrode;
a second electrode disposed opposite to the first electrode; and
at least two light-emitting units and at least one charge generation layer disposed between the first electrode and the second electrode;
wherein the charge generation layer is disposed between adjacent light-emitting units, at least one of the light-emitting units is doped with quantum dot light-emitting material, and light emitted by each of the light-emitting units is blended to form white light.

2. The display panel according to claim 1, wherein the quantum dot light-emitting material comprises a blue quantum dot light-emitting material, and at least one of the light-emitting units comprises a blue quantum dot light-emitting layer.

3. The display panel according to claim 1, wherein when a number of the light-emitting units doped with the quantum dot light-emitting material is two, the two light-emitting units are defined as a first light-emitting unit and a second light-emitting unit, respectively, and the first light-emitting unit is disposed opposite to the second light-emitting unit.

4. The display panel according to claim 3, further comprising a third light-emitting unit disposed between the first light-emitting unit and the second light-emitting unit, wherein the third light-emitting unit comprises a yellow organic light-emitting layer or an organic light-emitting layer formed by stacking the yellow organic light-emitting layer with a red organic light-emitting layer.

5. The display panel according to claim 4, wherein the at least one charge generation layer comprises a first charge generation layer and a second charge generation layer, the first charge generation layer is disposed between the first light-emitting unit and the third light-emitting unit, and the second charge generation layer is disposed between the third light-emitting unit and the second light-emitting unit.

6. The display panel according to claim 3, wherein a light-emitting material of the first light-emitting unit is same as a light-emitting material of the second light-emitting unit.

7. The display panel according to claim 1, wherein the quantum dot light-emitting material comprises cadmium-based quantum dots comprising at least one of cadmium sulfide, cadmium telluride, or cadmium selenide.

8. The display panel according to claim 1, wherein the quantum dot light-emitting material comprises at least one of silicon, germanium, zinc selenide, lead sulfide, lead selenide, indium phosphide, or indium arsenide.

9. The display panel according to claim 1, further comprising a hole transport layer, an electron transport layer, and an electron injection layer.

10. A method of manufacturing a display panel, comprising:
providing a first electrode, and forming at least two light-emitting units and at least one charge generation layer on the first electrode; and
forming a second electrode on the light-emitting unit or the charge generation layer;
wherein doping at least one of the light-emitting units with a quantum dot light-emitting material.

11. The method of manufacturing the display panel according to claim 10, wherein forming the light-emitting unit doped with the quantum dot light-emitting material adopts a wet process, comprising spray coating, silk rod coating, or roll-to-roll coating.

12. The method of manufacturing the display panel according to claim 10, wherein the quantum dot light-emitting material comprises a blue quantum dot light-emitting material, and at least one of the light-emitting units comprises a blue quantum dot light-emitting layer.

13. The method of manufacturing the display panel according to claim 10, wherein when a number of the light-emitting units doped with the quantum dot light-emitting material is two:
forming a first light-emitting unit and a second light-emitting unit, respectively;
and arranging the first light-emitting unit and the second light-emitting unit opposite to each other.

14. The method of manufacturing the display panel according to claim 13, further comprising;
forming a third light-emitting unit;
wherein the third light-emitting unit is formed between the first light-emitting unit and the second light-emitting unit, and the third light-emitting unit comprises a yellow organic light-emitting layer or an organic light-emitting layer formed by stacking a yellow organic light-emitting layer and a red organic light-emitting layer.

15. The method of manufacturing the display panel according to claim 14, wherein the at least one charge generation layer comprises a first charge generation layer and a second charge generation layer, wherein forming the first charge generation layer between the first light-emitting unit and the third light-emitting unit, and forming the second charge generation layer between the third light-emitting unit and the second light-emitting unit.

16. The method of manufacturing the display panel according to claim 13, wherein a light-emitting material forming the first light-emitting unit and light-emitting material of forming the second light-emitting unit are same.

17. The method of manufacturing the display panel according to claim 10, wherein the quantum dot light-emitting material comprises cadmium-based quantum dots comprising at least one of cadmium sulfide, cadmium telluride, or cadmium selenide.

18. The method of manufacturing the display panel according to claim 10, wherein the quantum dot light-emitting material comprises at least one of silicon, germanium, zinc selenide, lead sulfide, lead selenide, indium phosphide, or indium arsenide.

19. The method of manufacturing the display panel according to claim 10, further comprising;
forming a hole transport layer, an electron transport layer, and an electron injection layer; forming the hole transport layer on one surface of the first electrode;
forming the electron injection layer on one surface of the second electrode; and
forming the electron injection layer on one surface of the electron injection layer.
